(19) United States
(12) Patent Application Publication
(10) Pub. No.: US 2012/0146703 A1
(43) Pub. Date: Jun. 14, 2012

(54) APPARATUS AND METHOD FOR CALIBRATING SIGNAL

(75) Inventors: Gil Soo Jang, Seoul (KR); Gil Sung Byeon, Incheon (KR)

(73) Assignee: Korea University Research and Business Foundation

(21) Appl. No.: 13/151,808

(22) Filed: Jun. 2, 2011

(30) Foreign Application Priority Data
Jun. 4, 2010 (KR) 10-2010-0052929

(51) Int. Cl. H03L 5/00

(52) U.S. Cl. 327/307

(57) ABSTRACT

Provided is an apparatus and method for calibrating a signal, which extracts a plurality of signal samples from sine-wave input signals; calculates a real root of a DC component calculating condition derived using simultaneous equations for values of the signal samples; calculates a value of a DC component from the simultaneous equations by using the calculated real root; and removes the DC component by applying the calculated value of the DC component to the sine-wave input signals, wherein the number of signal samples extracted in the signal sample extracting step is set according to the number of unknown quantities of the simultaneous equations.

### CROSS-REFERENCE TO RELATED APPLICATION

This application claims priority to Korean Patent Application No. 10-2010-0052929, filed on Jun. 4, 2010, and all the benefits accruing therefrom under 35 U.S.C. §119, the contents of which in its entirety are herein incorporated by reference.

### TECHNICAL FIELD

The following disclosure relates to an apparatus and method for calibrating a signal. More particularly, the following disclosure relates to an apparatus and method for calibrating a signal by calculating and removing a direct current (DC) component value of an input signal.

### BACKGROUND

Recently, in regard to simulation analysis for electric power systems, real-time simulation analysis which can give the same result as an analysis in an actual circumstance has been actively studied.

In the real-time simulation analysis method, actual operating devices and test devices are connected to a real-time simulator to analyze an electric power system in real time, and a real-time simulation system composed of a real-time simulator and a device to be tested may be constructed. In the real-time simulation system, it is very important to ensure the accuracy of signals according to the kind and connection pattern of the simulator and the device to be tested.

In the real-time simulation system, signals may flow in one direction or in two directions. Depending on the purpose of analysis, the signal flow may be set to any one direction between the real-time simulator and the device to be tested.

At this time, in the real-time simulation system, signals transmitting between the real-time simulator and the device to be tested pass via an intermediate media such as an I/O device, a signal amplifier or a sensor. While signals are transmitting, the source signals may be easily distorted due to the signal error occurring at I/O terminals of the signal amplifier, noise at cables or electric wires, and influences of external circumstances (e.g., magnetic field).

If the signals transmitting in the real-time simulation system are not accurately calibrated, the accuracy of the overall simulation may be greatly influenced. In particular, in a case where signals flow bi-directionally, distorted signals may be fed back between two parts, which may rapidly spread an error pattern. In particular, among components of signals which are transmitting, a direct current (DC) offset component is successively accumulated as the analyzing time passes, and the simulation may become inaccurate due to the accumulated DC offset components.

Therefore, there is a need to develop a signal calibrating apparatus and method for calibrating a transmitting signal which has been distorted due to the inaccuracy of I/O devices connected to a real-time simulator and external circumstances to give an accurate simulation result.

### SUMMARY

This disclosure is designed to solve the above problem, and an embodiment of the present disclosure is directed to providing an apparatus and method for calibrating a signal, which may remove a high-frequency component and a direct current (DC) component of an input signal.

In addition, an embodiment of the present disclosure is directed to providing an apparatus and method for calibrating a signal, which may calculate a DC component value of an input signal within a short time.

Further, an embodiment of the present disclosure is directed to providing an apparatus and method for calibrating a signal, which may calculate a DC component according to the change of an input signal.

In one general aspect, an apparatus for calibrating a signal includes: a signal sample extracting unit for extracting a plurality of signal samples from sine-wave input signals; a DC component calculating unit for calculating a real root of a DC component calculating condition derived using simultaneous equations for values of the signal samples, and calculating a value of a DC component from the simultaneous equations by using the calculated real root; and a DC component removing unit for removing the DC component by applying the calculated value of the DC component to the sine-wave input signals, wherein the number of signal samples extracted by the signal sample extracting unit is set according to the number of unknown quantities of the simultaneous equations.

The DC component calculating unit may calculate the real root by means of the DC component calculating condition using an equation condition=(sin⁻¹((C−B)β)−sin⁻¹((B−A)β))−(sin⁻¹((D−C)β)−sin⁻¹((C−B)β)) where A, B, C and D are respectively values of the signal samples and β is an arbitrary constant.

In another aspect, a method for calibrating a signal includes: extracting a plurality of signal samples from sine-wave input signals; calculating a value of a DC component by calculating a real root of a DC component calculating condition derived using simultaneous equations for values of the signal samples; and removing the DC component of the sine-wave input signals by applying the calculated value of the DC component to the sine-wave input signals, wherein the number of signal samples extracted in the signal sample extracting step is set according to the number of unknown quantities of the simultaneous equations.

In the DC component calculating step, the real root may be calculated by the DC component calculating condition using an equation condition=(sin⁻¹((C−B)β)−sin⁻¹(B−A)β))−sin⁻¹((D−C)β)−sin⁻¹((C−B)β)) where A, B, C and D are respectively values of the signal samples and β is an arbitrary constant.

Other features and aspects will be apparent from the following detailed description, the drawings, and the claims.

### BRIEF DESCRIPTION OF THE DRAWINGS

The above and other objects, features and advantages of the present disclosure will become apparent from the following description of certain exemplary embodiments given in conjunction with the accompanying drawings, in which:

FIG. 1 is a block diagram showing an apparatus for calibrating a signal according to an exemplary embodiment;

FIG. 2 is a graph showing a trajectory of a direct current (DC) component calculating condition according to an exemplary embodiment;

FIG. 3 is a graph showing the change of a value of the DC component calculating condition according to the change of an arbitrary constant value according to an exemplary embodiment;

FIGS. 4 and 5 are a graph and a flowchart for illustrating one example of an iterative convergence algorithm for detecting a real root of the DC component calculating condition according to an exemplary embodiment;

FIGS. 6 and 7 are a graph and a flowchart for illustrating another example of an iterative convergence algorithm for detecting a real root of the DC component calculating condition according to an exemplary embodiment;

FIG. 8 is a flowchart illustrating an algorithm for calculating a DC component value by using the DC component calculating condition according to an exemplary embodiment; and

FIG. 9 is a flowchart for illustrating a method for calibrating a signal according to an exemplary embodiment.

### DETAILED DESCRIPTION OF EMBODIMENTS

The advantages, features and aspects of the present disclosure will become apparent from the following description of the embodiments with reference to the accompanying drawings, which is set forth hereinafter. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

Hereinafter, exemplary embodiments will be described in detail with reference to the accompanying drawings.

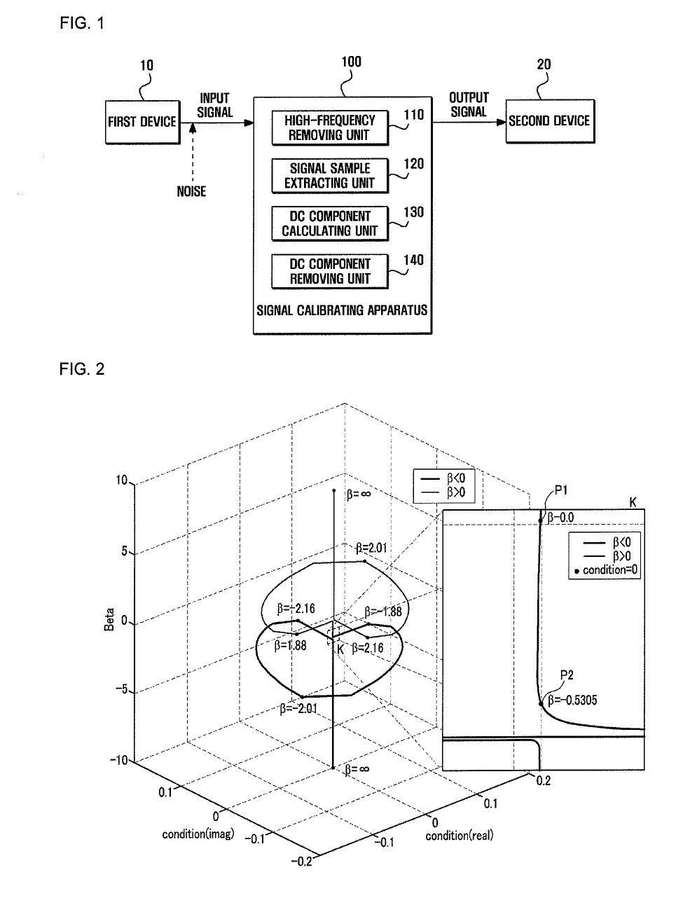

FIG. 1 is a block diagram showing an apparatus for calibrating a signal according to an exemplary embodiment.

As shown in FIG. 1, a signal calibrating apparatus 100 according to this embodiment receives a signal from a first device 10, calibrates the received signal (hereinafter, referred to as an ‘input signal’), and then outputs the calibrated signal (hereinafter, referred to as an ‘output signal’) to a second device 20.

For reference, the signal (or, the input signal) input to the signal calibrating apparatus 100 from the first device 10 is a source signal output from the first device 10, which is distorted due to the influence of noise. The source signal may be distorted due to various factors such as external circumstances or errors occurring between devices. At this time, the signal calibrating apparatus 100 removes a distorted component (in other words, a high-frequency component and direct current (DC) component) of the input signal.

In detail, the signal calibrating apparatus 100 includes a high-frequency component removing unit 110, a signal sample extracting unit 120, a DC component calculating unit 130, and a DC component removing unit 140.

The high-frequency component removing unit 110 is a low pass filter which removes a high-frequency component of an input signal (that is, an analog signal). At this time, the input signal from which a high-frequency component is removed is input to the signal sample extracting unit 120 and the DC component removing unit 140. For reference, the input signal may be a sine-wave signal.

The signal sample extracting unit 120 extracts a preset number of signal samples from the received input signal. At this time, signal samples are extracted at each preset extraction time intervals. In addition, the signal sample extracting unit 120 transmits the plurality of extracted signal samples to the DC component calculating unit 130. For reference, the value of the extracted signal sample is an amplitude value sampled from the input signal (e.g., a sine-wave signal) within a time region.

In detail, the signal sample extracting unit 120 according to this embodiment extracts four signal samples upon the request of the DC component calculating unit 130 and transmits the value of extracted signal samples to the DC component calculating unit 130. At this time, the input signal of this embodiment is a sine wave, and the value of the extracted signal sample is an amplitude value of the signal sample.

The DC component calculating unit 130 calculates a value of a DC component of the input signal according to simultaneous equations where the value of the signal samples is defined as a trigonometrical function and a DC component calculating condition derived from the simultaneous equations. In addition, the DC component calculating unit 130 transmits the calculated value of the DC component to the DC component removing unit 140.

A method for calculating a value of a DC component according to simultaneous equations and a DC component calculating condition for the value of the signal sample by the DC component calculating unit 130 will be described later in detail with reference to FIGS. 2 to 8.

The DC component removing unit 140 applies the DC component value calculated by the DC component calculating unit 130 to the input signal to remove the DC component and then outputs the signal free from the DC component. Therefore, the signal (or, the output signal) output from the DC component removing unit 140 is free from a high-frequency component and a DC component.

Hereinafter, a method for deriving a DC component calculating condition and calculating a DC component value by calculating a real root of the DC component calculating condition according to an exemplary embodiment, executed by the DC component calculating unit 130, will be described in detail with reference to FIGS. 2 to 7.

FIG. 2 is a graph showing a trajectory of the DC component calculating condition of an exemplary embodiment.

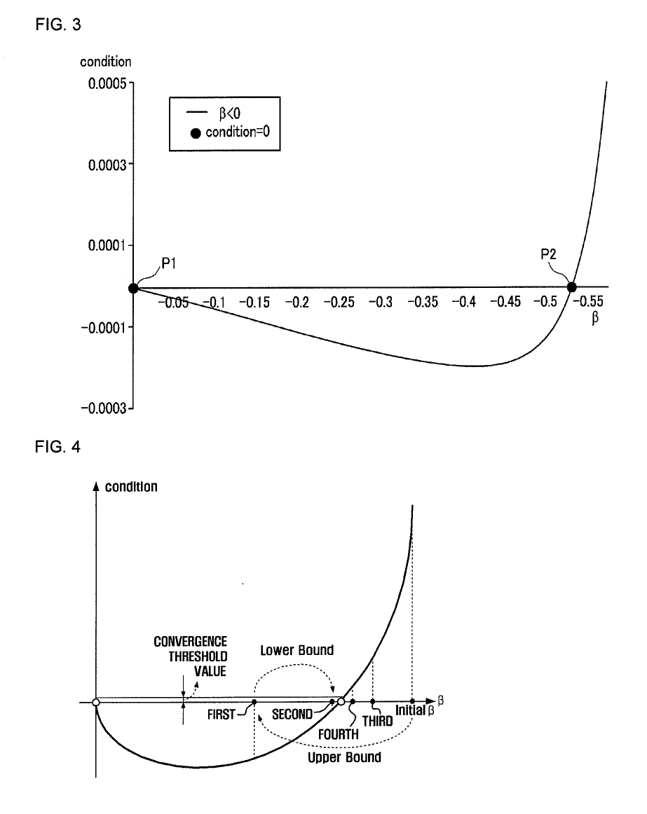

FIG. 3 is a graph showing the change of a value of the DC component calculating condition according to the change of an arbitrary constant value according to an exemplary embodiment.

First, simultaneous equations for a value of the signal sample and a method for deriving the DC component calculating condition according to this embodiment, performed by the DC component calculating unit 130, will be described. In addition, the following description is based on the assumption that the signal sample extracting unit 120 extracts four signal samples at each extraction, and values of the extracted signal samples are respectively called A, B, C and D. For reference, the number of samples extracted by the signal sample extracting unit 120 may be set based on the number of unknown quantities among parameters of the simultaneous equations used for deriving the DC component calculating condition.

Values of the signal samples input to the DC component calculating unit 130 are defined with a cosine (cos) function respectively as in the following equations 1 to 4.

A=V_{M} cos(2πft)+α (1)

B=V_{M} cos(2πf(t+Δt))+α (2)

C=V_{M} cos(2πf(t+2Δt))+α(3)

D=V_{M} cos(2πf(t+3Δt))+α (4)

In Equations (1) to (4), A, B, C and D are respectively values of signal samples extracted from input signals, and At is a value of a time interval (or, an extraction time interval) at which signal samples are extracted. In addition, V_{M} is an amplitude value of the input signal, f is a frequency of the input signal, t is a time value of the input signal, and α is a value of the DC component of the input signal, wherein V_{M}, f, t and α are unknown quantities. For reference, assuming that differences of DC components (α_{A}, α_{B}, α_{C} and a_{D}) of the signal samples are very small (α_{A}≅α_{B}≅_{C}≅α_{D}), the DC component of each signal sample may be expressed as α.

After that, in order to remove the unknown quantity α, Equations (1) to (4) are calculated as simultaneous equations. In other words, Equation (1) is subtracted from Equation (2), Equation (2) is subtracted from Equation (3), and Equation (3) is subtracted from Equation (4). After that, both terms are divided by V_{M} to define Equations (5) to (7) as follows.

$$\begin{matrix}\frac{B - A}{{V}_{M}} = cos ( 2 π f ( t + Δ t ) ) - cos ( 2 π f t ) & ( 5 ) \\ \frac{C - B}{{V}_{M}} = cos ( 2 π f ( t + 2 Δ t ) ) - cos ( 2 π f ( t + Δ t ) ) & ( 6 ) \\ \frac{D - C}{{V}_{M}} = cos ( 2 π f ( t + 3 Δ t ) ) - cos ( 2 π f ( t + 2 Δ t ) ) & ( 7 )\end{matrix}$$

After that, Equations (5) to (7) are defined again into Equations (8) to (10) as follows by using a trigonometrical function equation.

$$\begin{matrix}\begin{matrix}\frac{B - A}{{V}_{M}} = - 2 sin ( \frac{2 π f ( 2 t + Δ t )}{2} ) sin ( \frac{2 π f Δ t}{2} ) \\ = - 2 sin ( π f ( 2 t + Δ t ) ) sin ( π f Δ t )\end{matrix} & ( 8 ) \\ \frac{C - B}{{V}_{M} } = - 2 sin ( π f ( 2 t + 3 Δ t ) ) sin ( π f Δ t ) & ( 9 ) \\ \frac{D - C}{{V}_{M}} = - sin ( π f ( 2 t + 5 Δ t ) ) sin ( π f Δ t ) & ( 10 )\end{matrix}$$

After that, in order to remove the unknown quantity V_{M}, Equation (9) is divided by Equation (8), and Equation (10) is divided by Equation (9) to derive Equations (11) and (12) as follows.

$$\begin{matrix}\frac{C - B}{ B - A} = \frac{sin ( π f ( 2 t + 3 Δ t ) )}{sin ( π f ( 2 t + Δ t ) )} & ( 11 ) \\ \frac{D - C}{C - B} = \frac{sin ( π f ( 2 t + 5 Δ t ) )}{sin ( π f ( 2 t + 3 Δ t ) )} & ( 12 )\end{matrix}$$

After that, Equations (13) to (15) are derived from Equations (11) and (12) by using an arbitrary constant β. At this time, the arbitrary constant β is an arbitrary constant assumed to satisfy Equations (13) to (15) as follows.

(B−A)β=sin(πf(2t+Δt)) (13)

(C−B)β=sin(πf(2t+3Δt)) (14)

(D−C)=sin(πf(2t+5Δt)) (15)

After that, Equations (13) to (15) are defined again into Equations (16) to (18) as follows by using sin⁻¹.

πf(2t+Δt)=sin⁻¹((B−A)β) (16)

πf(2t+3Δt)=sin⁻¹((C−B)β) (17)

πf(2t+5Δt)=sin⁻¹((D−C)β) (18)

After that, Equation (16) is subtracted from Equation (17), and Equation (17) is subtracted from Equation (18) to derive Equations (19) and (20) as follows.

sin⁻¹((C−B)β)−sin⁻¹((B−A)β)=2πfΔt (19)

sin⁻¹((D−C)β)−sin⁻¹((C−B)β)=2πfΔt (20)

At this time, it could be found that the value obtained by subtracting Equation (20) from Equation (19) is always 0 (zero) if β is selected appropriately. In other words, a DC component calculating condition may be defined by the difference of Equations (19) and (20).

The DC component calculating condition as mentioned above may be represented by Equation (21) as follows.

condition=(sin⁻¹((C−B)β)−sin⁻¹((B−A))−(sin⁻¹((D−C)β)−sin⁻¹((C−B)β)) (21)

Meanwhile, the arbitrary constant β assumed in Equations (13) to (15) is influenced by the amplitude V_{M} and the frequency f of the input signal but not influenced by the time t and the DC component α. Therefore, if the condition that the amplitude V_{M} and the frequency f are constant is satisfied in Equations (1) to (20), β satisfying Equations (13) to (15) is identical in all time regions. At this time, a β value (or, a real root) satisfying that the value of the DC component calculating condition shown in Equation (21) is 0 may be calculated.

If the β value (or, the real root) is determined as mentioned above, the determined β value is applied to Equations (19) and (20) to calculate a frequency f, and the calculated frequency f is applied to Equations (13) to (15) to calculate a time t. After that, the calculated frequency f and time t are applied to Equations (5) to (7) to calculate an amplitude V_{M}, and the calculated frequency f, time t and amplitude V_{M} are applied to Equations (1) to (4) to calculate a DC component a of the input signal.

Meanwhile, the DC component calculating unit 130 according to this embodiment may calculate a specific β (or, a real root) using an algorithm by iterative convergence.

The value of the DC component calculating condition according to this embodiment may be a complex number or a real number according to the change of the β value.

For example, FIG. 2 shows a trajectory of the DC component calculating condition value according to the change of the β value when the input signal has an amplitude of V_{M}=100, an extraction time interval of Δt=50e−6 sec, a frequency of f=60 Hz and a time of t=2.5e−3 sec (50 Δt). At this time, FIG. 2 shows a trajectory of the DC component calculating condition value when the β value changes from −∞ to 0 and a trajectory of the DC component calculating condition value when the β value changes from 0 to ∞ with solid lines having different thicknesses. In other words, the trajectory of the DC component calculating condition when the β value is less than 0 is thicker than the trajectory of the DC component calculating condition when the β value is greater than 0. At this time, the β value (or, the real root) which converges the DC component calculating condition value to 0 is present on the trajectory when the β value changes from −∞ to 0.

In detail, in the graph of FIG. 2 showing the K portion enlarged, the vertical axis represents β, and the horizontal axis represents a real number region of the DC component calculating condition value. At this time, FIG. 2 shows that the β values (or, the real roots) (P1 and P2) satisfying that the DC component calculating condition value is 0 are present in a region when β=0 and 0<β<−1.88. At this time, when β=0, the β value is an imaginary root not satisfying Equations (13) to (15), and the β value present in the region of 0<β<−1.88 becomes a real root. For reference, β always has a negative value due to Equations (13) to (15).

Meanwhile, as shown in FIG. 3, when β is 0 (P1), the DC component calculating condition value becomes 0. In addition, as the β value decreases, the DC component calculating value gradually decreases and then increases so as to be 0 again at a specific β value (P2). After that, if the β value becomes smaller than the specific β value, the DC component calculating condition value increases further to have a complex number.

At this time, the DC component calculating unit 130 according to this embodiment may detect the specific β value (or, the real root) by applying a β value changed according to the DC component calculating condition value after an initial β value (Initial β) is set, by means of an iterative convergence algorithm which makes the DC component calculating condition value be converged to 0.

Hereinafter, an example of the iterative convergence algorithm for detecting a real root of a DC component calculating condition according to an exemplary embodiment will be described in detail with reference to FIGS. 4 to 7.

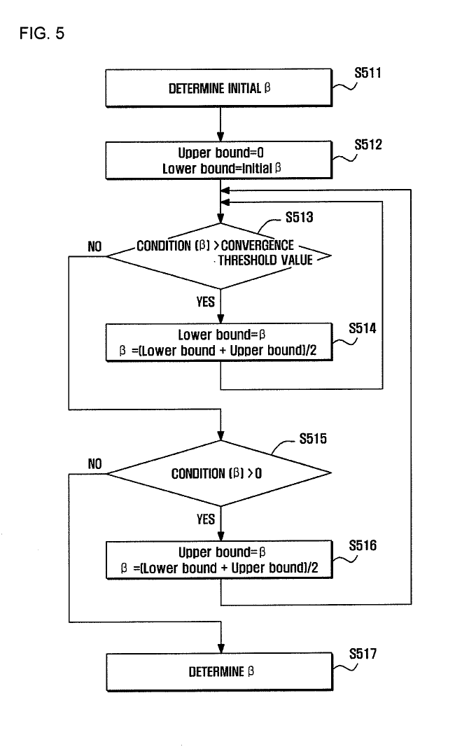

FIGS. 4 and 5 are a graph and a flowchart for illustrating an example of the iterative convergence algorithm for detecting a real root of a DC component calculating condition according to this embodiment.

At this time, FIGS. 4 and 5 show an iterative convergence algorithm where upper and lower bounds of the β value are defined again and again in order to detect the specific β value according to this embodiment.

For example, FIG. 4 is a graph showing the change of a value the DC component calculating condition (hereinafter, referred to as ‘the condition’) according to the change of an arbitrary constant β. At this time, in the iterative convergence algorithm where upper and lower bounds of a β value are defined again and again according to this embodiment, the upper and lower bounds are defined again and again according to the relation between a resultant value of the condition to which the selected β value is applied and a preset convergence threshold value.

In other words, as shown in FIG. 4, if a resultant value (or, a condition value) obtained by applying a previously selected β value to the condition is less than a minimum value (or, 0) within the range of the convergence threshold value, the upper bound is defined again as a smaller value so that a value smaller than the previously selected β value may be selected as the β value. Meanwhile, if a resultant value obtained by applying a previously selected β value to the condition is greater than a maximum value (or, a convergence threshold value) within the range of the convergence threshold value, the lower bound is defined again as a greater value so that a value greater than the previously selected value may be selected as the β value.

In detail, FIG. 5 is a flowchart showing an iterative convergence algorithm for defining upper and lower bounds of a β value again.

First, an initial β value (Initial which will be initially applied to the DC component calculating condition is determined (S511).

For reference, since the initial β value is assumed as a maximum value of the right term in Equations (13) to (15) (in this embodiment, the initial β value is set to 1 which is a maximum value of a sine wave), the initial β value is always set to be smaller than a real root.

After that, the ranges of upper and lower bounds (or, the range of selectable β value) are set so that the upper bound is 0, and the lower bound is the initial β value (Initial β) (S512).

Then, the selected β value is applied to the condition and it is determined whether the resultant value (condition β) is greater than a preset convergence limit (S513).

At this time, the selected β value is increased or decreased as much as a preset value according to the condition value to which the previously selected β value is applied, and β values selected from the initial β value are applied to the condition in order. In a case the initial β value is applied to the condition, the ranges of upper and lower bounds of the β value are already set from 0 to the initial β value, as described in S512.

In addition, the convergence threshold value has the same concept as the convergence threshold value shown in FIG. 4. In the iterative convergence algorithm according to this embodiment, a β value with which the condition value is converged within a certain range based on 0 (or, a convergence threshold value) may be selected as a real root. For reference, FIG. 4 shows that the convergence threshold value has a positive value.

After that, if the value obtained by applying the selected β value to the condition is greater than the convergence threshold value as a result of the determination of S513, the lower bound is set to be the selected β value, and then a value obtained by dividing the sum of the upper and lower bounds by 2 is selected as a β value which will be applied in the next time (S514). After that, the process returns to S513.

Meanwhile, if the resultant value (condition β) obtained by applying the selected β value to the condition is equal to or smaller than the convergence threshold value as a result of the determination of S513, it is determined whether the resultant value (condition β) obtained by applying the selected β value to the condition is smaller than 0 (S515).

At this time, if the resultant value (condition β) obtained by applying the selected β value to the condition is smaller than 0 (or, a negative value) as a result of the determination of S515, the upper bound is set to the selected β value, and then a value obtained by dividing the sum of the upper and lower bounds by 2 is selected as a β value which will be applied in the next time (S516). After that, the process returns to S513.

In addition, if the resultant value (condition β) obtained by applying the selected β value to the condition is equal to or greater than 0 as a result of the determination of S515, the selected β value is determined as a real root (S517).

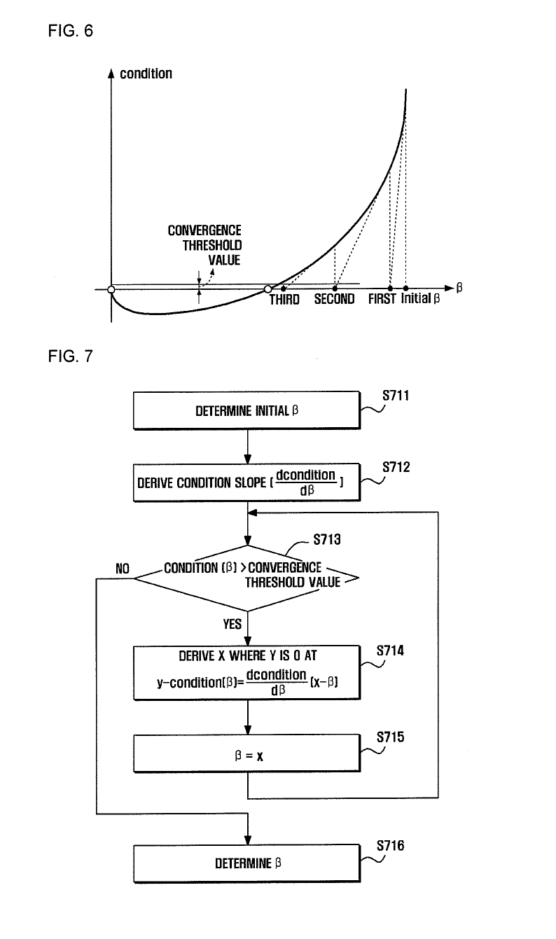

FIGS. 6 and 7 are a graph and a flowchart for illustrating another example of the iterative convergence algorithm for detecting a real root of the DC component calculating condition according to this embodiment.

At this time, FIGS. 6 and 7 show an iterative convergence algorithm by a slope of the condition according to the applied β value, in order to detect the specific β value according to this embodiment.

For example, FIG. 6 is a graph showing the change of a value of the DC component calculating condition (hereinafter, referred to as ‘the condition’) according to the change of an arbitrary constant β. At this time, in the iterative convergence algorithm by a slope of the condition according to the β value, a value of the x axis satisfying, that y value of a slope function in the condition to which a previously selected β value is applied is 0, is selected as a β value which will be applied in the next time.

In other words, as shown in FIG. 6, the process of applying a value of the x axis, satisfying that y value of the slope function is 0 in the condition to which a previously selected β value is applied, to the condition is iteratively performed, until the value of the condition becomes smaller than the convergence threshold value.

In detail, FIG. 7 is a flowchart showing an iterative convergence algorithm by a slope of the condition according to the β value.

First, an initial β value (Initial β) which is initially applied to the condition is determined (S711).

For reference, since the initial β value is assumed as a maximum value of the right term in Equations (13) to (15) (in this embodiment, the initial β value is set to 1 which is a maximum value of a sine wave), the initial β value is always set to be smaller than a real root.

After that, a slope function

$$\frac{d condition}{d β}$$

of the condition to which the selected β value is applied is derived (S712).

After that, it is determined whether a resultant value (condition β) obtained by applying the selected β value to the condition is greater than the convergence threshold value (S713).

At this time, if the resultant value (condition β) obtained by applying the selected β value to the condition is greater than the convergence threshold value as a result of the determination of S713, a domain x value satisfying that a codomain y value is 0 in a slope function

$$y - condition ( β ) = \frac{d condition}{d β} ( x - β )$$

of the condition is calculated (S714).

After that, the β value is set to the calculated x value and selected as a β value which will be applied to the condition in the next time (S715). After that, the process returns to S713.

Meanwhile, if the resultant value (condition β) obtained by applying the selected β value to the condition is equal to or smaller than the convergence threshold value as a result of the determination of S713, the selected β value is determined as a real root (S716).

As described above, a real root which converges the condition value to 0 may be detected by means of the iterative convergence algorithm of the DC component calculating condition described with reference to FIGS. 4 to 7. At this time, as the real root (or, the β value) is more accurate, the frequency f calculated through Equations (19) and (20) may be calculated more accurately. In other words, when the real root is detected using the iterative convergence algorithm according to this embodiment, as the convergence threshold value is set smaller, a more accurate real root may be detected.

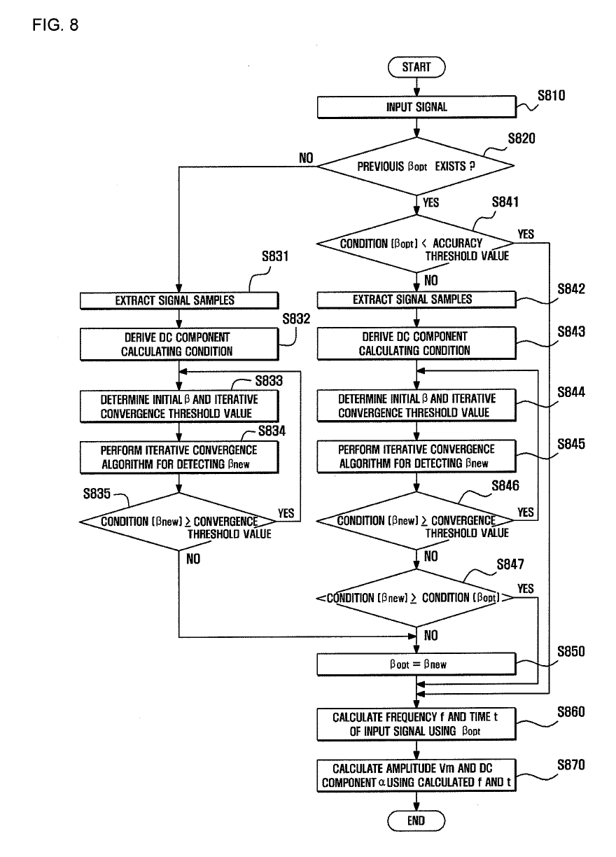

Hereinafter, a process of calculating a DC component value by the DC component calculating unit 130 according to an exemplary embodiment will be described with reference to FIG. 8.

FIG. 8 is a flowchart showing an algorithm for calculating a DC component value using the DC component calculating condition according to this embodiment.

First, if a signal (or, an input signal) is input (S810), it is determined whether βₒₚₜ is present (S820).

At this time, the input signal may be an analog sine-wave signal, and βₒₚₜ means a real root of a preset DC component calculating condition.

After that, if the preset βₒₚₜ is not present as a result of the determination of S820, a preset number of signal samples are extracted from the input signals (S831).

In addition, a DC component calculating condition is derived using simultaneous equations for the extracted signal samples (S832).

The simultaneous equations and the DC component calculating condition may be defined using Equations (1) to (21). At this time, the DC component calculating unit 130 according to this embodiment may derive and store the simultaneous equations and the DC component calculating condition in advance as experimental data and may execute S832 by detecting a stored equation which matches up with values of the signal samples and an extraction time interval value for the signal samples.

After that, in order to calculate a real root (or, a β value) satisfying the DC component calculating condition obtained in S832, an initial β value and an iterative convergence threshold value are determined (S833).

For reference, the iterative convergence threshold value may be set to be identical to the convergence threshold value described in FIGS. 4 to 7.

After that, in order to calculate a β value (β_{new}) which will be applied to the DC component calculating condition, the iterative convergence algorithm is performed using the set initial β value and the iterative convergence threshold value (S834).

For reference, the iterative convergence algorithm performed in S834 may be the iterative convergence algorithm described in FIGS. 4 to 7.

After that, it is determined whether a resultant value (condition β_{new}) of the DC component calculating condition to which β_{new} detected by the iterative convergence algorithm in S834 is applied has a value equal to or greater than the convergence threshold value (S835).

At this time, if the resultant value (condition β_{new}) of the DC component calculating condition to which β_{new} is applied has a value equal to or greater than the convergence threshold value as a result of the determination of S835, S834 is executed again to detect β_{new} again.

For reference, though S835 is described to determine whether the resultant value (condition β_{new}) of the DC component calculating condition has a value equal to or greater than the convergence threshold value, S835 may be modified to determine whether the resultant value of the DC component calculating condition has a value greater than the convergence threshold value, as shown in FIGS. 5 to 7.

Meanwhile, if the resultant value (condition β_{new}) of the DC component calculating condition to which β_{new} is applied has a value smaller than the convergence threshold value as a result of the determination of S835, the corresponding flnew is updated as a real root βₒₚₜ (S850).

In other words, if there is no preset real root of the DC component calculating condition for the input signal, S831 to S835 are executed to generate a real root of the DC component calculating condition.

Meanwhile, if it is determined that there exists a preset βₒₚₜ as a result of the determination of S820, it is determined whether a resultant value (condition βₒₚₜ) of the DC component calculating condition to which the corresponding βₒₚₜ is applied has a value smaller than a preset accuracy threshold value (S841).

At this time, the accuracy threshold value may be set to be identical to the iterative convergence threshold value and the convergence threshold value, and the accuracy threshold value may also be set to be smaller than the iterative convergence threshold value and the convergence threshold value in order to detect an accurate real root.

If the resultant value βₒₚₜ (condition βₒₚₜ) of the DC component calculating condition to which the preset βₒₚₜ is applied has a value smaller than the preset accuracy threshold value as a result of the determination of S841, a frequency f and time t for the input signal are calculated using the preset βₒₚₜ without updating βₒₚₜ (S860).

Meanwhile, if the resultant value (condition βₒₚₜ) of the DC component calculating condition to which the preset βₒₚₜ is applied has a value equal to or greater than the accuracy threshold value as a result of the determination of S841, a preset number of signal samples are extracted from the input signals (S842).

In addition, a DC component calculating condition is derived using simultaneous equations for the extracted signal samples (S843).

The simultaneous equations and the DC component calculating condition may be defined using Equations (1) to (21). At this time, the DC component calculating unit 130 according to this embodiment may derive and store the simultaneous equations and the DC component calculating condition in advance as experimental data and may execute S843 by detecting a stored equation which matches up with values of the signal samples and an extraction time interval value for the signal samples.

After that, in order to calculate a real root (or, a β value) satisfying the DC component calculating condition obtained in S843, an initial β value and an iterative convergence threshold value are determined (S844).

For reference, the iterative convergence threshold value may be set to be identical to the convergence threshold value described in FIGS. 4 to 7.

After that, in order to calculate a β value (β_{new}) which will be applied to the DC component calculating condition, the iterative convergence algorithm is performed using the set initial β value and the iterative convergence threshold value (S845).

For reference, the iterative convergence algorithm performed in S845 may be the iterative convergence algorithm described in FIGS. 4 to 7.

After that, it is determined whether a resultant value (condition β_{new}) of the DC component calculating condition to which β_{new} detected by the iterative convergence algorithm in S845 is applied has a value equal to or greater than the convergence threshold value (S846).

At this time, if the resultant value (condition β_{new}) of the DC component calculating condition to which β_{new} is applied has a value equal to or greater than the convergence threshold value as a result of the determination of S846, S845 is executed again to detect β_{new} again.

For reference, though S846 is described to determine whether the resultant value (condition β_{new}) of the DC component calculating condition has a value equal to or greater than the convergence threshold value, S846 may be modified to determine whether the resultant value of the DC component calculating condition has a value greater than the convergence threshold value, as shown in FIGS. 5 to 7.

Meanwhile, if the resultant value (condition flnew) of the DC component calculating condition to which β_{new} is applied has a value smaller than the convergence threshold value as a result of the determination of S846, it is determined whether the resultant value (condition β_{new}) of the DC component calculating condition to which β_{new} is applied has a value equal to or greater than a resultant value (condition β^{opt}) of the DC component calculating condition to which a preset βₒₚₜ is applied (S847).

After that, if the resultant value (condition β_{new}) of the DC component calculating condition to which β_{new} is applied has a value smaller than the resultant value (condition β^{opt}) of the DC component calculating condition to which a preset βₒₚₜ is applied as a result of the determination of S847, the corresponding flnew is updated as a real root βₒₚₜ (S850).

Then, a frequency f and time t for the input signals are calculated using βₒₚₜ updated in S850 (S860).

Meanwhile, if the resultant value (condition β_{new}) of the DC component calculating condition to which β_{new} is applied has a value equal to or greater than the resultant value (condition) of the DC component calculating condition to which a preset β^{opt} is applied as a result of the determination of S847, a frequency f and time t for the input signals are calculated using the stored βₒₚₜ without updating βₒₚₜ (S860).

In other words, if a β value (or, a real root) is determined in any one of the steps prior to S860, the determined β value is applied to Equations (19) and (20) to calculate a frequency f. In addition, the calculated frequency f is applied to Equations (13) to (15) to calculate a time t.

After that, amplitude V_{M} for the input signals is calculated using the calculated frequency f and time t, and a DC component a is calculated (S870).

At this time, the frequency f and time t may be applied to Equations (5) to (7) to calculate the amplitude V_{M} for the input signals, and the calculated frequency f, time t and amplitude V_{M} may be applied to Equations (1) to (4) to calculate the DC component α of the input signals.

As described above, in the algorithm for calculating a DC component value according to this embodiment, if there exists βₒₚₜ which satisfies a condition value smaller than the accuracy threshold value, it is not needed to calculate the DC component α whenever input signals of the same pattern are input successively, which enhances the operation efficiency. In addition, in the algorithm for calculating a DC component value according to this embodiment, in a case where the pattern of input signals is changed or a condition value is greater than the accuracy threshold value, a suitable βₒₚₜ is calculated by iterative convergence to update βₒₚₜ, which allows the change of input signals to be rapidly dealt.

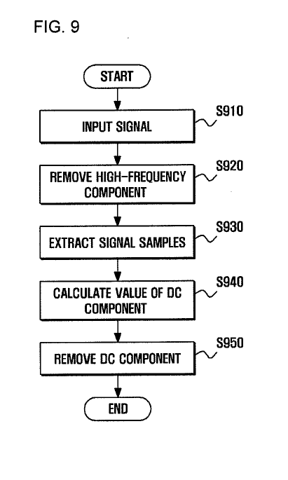

Hereinafter, a method for calibrating a signal according to an exemplary embodiment will be described with reference to FIG. 9.

FIG. 9 is a flowchart for illustrating the method for calibrating a signal according to this embodiment.

First, if a signal is input (S910), a high-frequency component of the input signal is removed (S920).

At this time, the input signal may be an analog signal (for example, a sine-wave signal), and a high-frequency component of the input signal is removed through the low-pass filtering process.

A preset number of signal samples are extracted from the input signals from which a high-frequency component is removed (S930).

A DC component value for the input signal is calculated using values of the extracted signal samples (S940).

At this time, in S940, a DC component value may be calculated using the DC component calculating algorithm illustrated in FIG. 8.

In detail, in the method for calibrating a signal according to this embodiment, it may be further determined whether the input signal is identical to a previously input signal, prior to performing the step of extracting signal samples. In other words, it may be determined whether a preset real root satisfying the preset DC component calculating condition exists. If a preset real root exists, a DC component value may be calculated using the preset real root or by calculating a more accurate real root than the preset real root.

After that, the DC component value is applied to the, input signal from which a high-frequency component is removed to remove the DC component (S950).

As described above, in the method for calibrating a signal according to this embodiment, since a preset number of signal samples are extracted from the input signals to perform the DC component calculating algorithm, a condition (or, a signal sample) for calculating a DC component may be obtained before one cycle of the input signal is performed. Therefore, a DC component may be calculated and removed rapidly and accurately.

The embodiment disclosed herein may be implemented as a recording medium including computer-readable commands, such as program modules executed by a computer. The computer-readable recording medium may be any useable medium which can be accessed by a computer, and it may be any of volatile and non-volatile media and separating and non-separating media. In addition, the computer-readable recording medium may be any of computer-storing media and communication media. The computer-storing medium may be any of volatile and non-volatile media and separating and non-separating media, which are implemented by any method or technique to store information such as computer-readable commands, data structures, program modules or other data. The communication medium includes computer-readable commands, data structures, program modules, other data of modulated data signals such as carrier wave signals, or other transmission mechanism as well as any information transmission medium. The apparatus and method according to this disclosure been illustrated based on specific embodiments, but its components or operations may be entirely or partly implemented using a computer system having a general hard architecture.

According to this disclosure, a distorted signal may be calibrated by effectively removing a high-frequency component and a DC component of an input signal.

According to this disclosure, a DC component value may be efficiently calculated through an equation derived using signal samples extracted from input signals.

According to this disclosure, a DC component value of an input signal may be calculated within a short time by extracting a plurality of successive signal samples from input signals at regular time intervals and then calculating the DC component value.

According to this disclosure, a DC component value may not be calculated at every signal input since a new DC component value is calculated only when the input signal is changed.

According to this disclosure, an accurate DC component value may be calculated within a short time by calculating a real root of the equation by using an iterative convergence algorithm when a DC component value of the input signal is calculated.

While the present disclosure has been described with respect to the specific embodiments, it will be apparent to those skilled in the art that various changes and modifications may be made without departing from the spirit and scope of the disclosure as defined in the following claims.

### REFERENCE NUMERALS

100: signal calibrating apparatus 110: high-frequency removing unit

120: signal sample extracting unit 130: DC component calculating unit

140: DC component removing unit

What is claimed is:

1. An apparatus for calibrating a signal, comprising:
a signal sample extracting unit for extracting a plurality of signal samples from sine-wave input signals;
a direct current (DC) component calculating unit for calculating a real root of a DC component calculating condition derived using simultaneous equations for values of the signal samples, and calculating a value of a DC component from the simultaneous equations by using the calculated real root; and
a DC component removing unit for removing the DC component by applying the calculated value of the DC component to the sine-wave input signals,
wherein the number of signal samples extracted by the signal sample extracting unit is set according to the number of unknown quantities of the simultaneous equations.

2. The apparatus according to claim 1, wherein the DC component calculating unit calculates the value of the DC component by applying the calculated real root to the simultaneous equations in which frequency of the sine-wave input signals, time of the sine-wave input signals, amplitude of the sine-wave input signals and value of the DC component are set as the unknown quantities.

3. The apparatus according to claim 1, wherein the DC component calculating unit calculates the real root by using a resultant value obtained by applying an arbitrary constant satisfying the simultaneous equations to the DC component calculating condition.

4. The apparatus according to claim 3, wherein the DC component calculating unit calculates the real root by changing any one of upper and lower bounds of the arbitrary constant until the resultant value becomes smaller than a preset threshold value and then applying the arbitrary constant, which is reset in the changing process, to the DC component calculating condition.

5. The apparatus according to claim 3, wherein the DC component calculating unit calculates the real root by resetting the arbitrary constant using a slope function regarding the resultant value until the resultant value becomes smaller than a preset threshold value, and then applying the reset arbitrary constant to the DC component calculating condition.

6. The apparatus according to claim 1, wherein the number of unknown quantities of the simultaneous equations is identical to the number of the extracted signal samples.

7. The apparatus according to claim 1, further comprising a high-frequency component removing unit for performing low-pass filtering to an input source signal and then outputting the filtered signal to the signal sample extracting unit.

8. The apparatus according to claim 1, wherein the signal sample extracting unit extracts a plurality of signal samples which are successive at preset extraction time intervals.

9. A method for calibrating a signal, comprising:
extracting a plurality of signal samples from sine-wave input signals;
calculating a value of a DC component by calculating a real root of a DC component calculating condition derived using simultaneous equations for values of the signal samples; and
removing the DC component of the sine-wave input signals by applying the calculated value of the DC component to the sine-wave input signals,
wherein the number of signal samples extracted in the signal sample extracting step is set according to the number of unknown quantities of the simultaneous equations.

10. The method according to claim 9, further comprising: removing a high-frequency component from a source signal of the sine-wave input signals, before the signal sample extracting step is executed.

11. The method according to claim 9, further comprising: determining whether a preset real root exists regarding the DC component calculating condition, before the signal sample extracting step is executed,
wherein the preset real root is applied to the simultaneous equations to calculate the value of the DC component if the preset real root exists.

12. The method according to claim 9, wherein, in the DC component calculating step, the real root is applied to the simultaneous equations in which frequency of the sine-wave input signals, time of the sine-wave input signals, amplitude of the sine-wave input signals and value of the DC component are set as the unknown quantities, in order to calculate the value of the DC component.

13. The method according to claim 9, wherein the DC component calculating step includes:
changing an arbitrary constant satisfying the simultaneous equations according to a preset rule and applying the changed arbitrary constant to the DC component calculating condition; and
setting the applied arbitrary constant value to the real root when a resultant value obtained by applying the arbitrary constant value to the DC component calculating condition is included within a preset threshold range.

14. The method according to claim 13, wherein the step of changing an arbitrary constant and applying the changed arbitrary constant to the DC component calculating condition includes:
changing the arbitrary constant by setting an upper bound of the arbitrary constant to be smaller than a preset upper bound in a case where the resultant value is greater than a highest value within the threshold range; or
changing the arbitrary constant by setting a lower bound of the arbitrary constant to be greater than a preset lower bound in a case where the resultant value is smaller than a lowest value within the threshold range.

15. The method according to claim 14, wherein the upper bound is initially set to be 0 (zero), and the lower bound is initially set to be smaller than the real root.

16. The method according to claim 13, wherein, in the step of changing an arbitrary constant and applying the changed arbitrary constant to the DC component calculating condition, in a case where the resultant value is greater than a highest value within the threshold range, a domain where a codomain of a slope function for the resultant value is 0 is calculated so that the arbitrary constant is changed to the calculated domain value.

17. The method according to claim 9, wherein the number of unknown quantities of the simultaneous equations is identical to the number of the extracted signal samples.

18. The method according to claim 9, wherein, in the signal sample extracting step, a plurality of signal samples which are successive at preset extraction time intervals are extracted.
